(19) United States
(12) Patent Application Publication
(10) Pub. No.: US 2014/0340488 A1
(43) Pub. Date: Nov. 20, 2014

(54) IMAGE CAPTURING APPARATUS

(71) Applicant: NIKON CORPORATION, Tokyo (JP)

(72) Inventors: Kiyoshige SHIBAZAKI, Higashimurayama-shi (JP); Muneki HAMASHIMA, Fukaya-shi (JP); Susumu MORI, Tokyo (JP)

(21) Appl. No.: 14/448,373

(22) Filed: Jul. 31, 2014

Related U.S. Application Data
(63) Continuation of application No. PCT/JP2013/000576, filed on Feb. 1, 2013.

(30) Foreign Application Priority Data
Feb. 1, 2012 (JP) 2012-020363

(51) Int. Cl. H04N 13/02; H04N 5/238

(52) U.S. Cl. CPC H04N 13/0217; H04N 13/0282; H04N 5/238
USPC 348/49

(57) ABSTRACT

In order to provide an image capturing apparatus with a simple configuration that can acquire a parallax image, the image capturing apparatus comprises an image capturing element including photoelectric converting elements that are arranged two-dimensionally and photoelectrically convert incident light into an electrical signal, and an aperture mask including apertures provided to correspond one-to-one with the photoelectric converting elements and positioned in a manner to pass light from different partial regions in a cross-sectional region of the incident light, and a diaphragm that changes shape while maintaining a state in which width of a diaphragm aperture in an arrangement direction of the different partial regions is greater than width of the diaphragm aperture in a direction orthogonal to the arrangement direction.

The contents of the following Japanese patent applications are incorporated herein by reference:

NO. 2012-020363 filed on Feb. 1, 2012 and

PCT/JP2013/000576 filed on Feb. 1, 2013.

### BACKGROUND

1. Technical Field

The present invention relates to an image capturing apparatus.

2. Related Art

A stereo image capturing apparatus is known that uses two image capturing optical systems to capture a stereo image formed by a left eye image and a right eye image. This stereo image capturing apparatus causes a parallax in the two images acquired from capturing the same subject, by arranging the two image capturing optical systems at a prescribed distance from each other.

Patent Document Japanese Patent Application Publication No. H8-47001

However, in order to capture parallax images, it is necessary to prepare an image capturing element and a complex image capturing system to acquire each parallax image.

### SUMMARY

Therefore, it is an object of an aspect of the innovations herein to provide an image capturing apparatus, which is capable of overcoming the above drawbacks accompanying the related art. The above and other objects can be achieved by combinations described in the claims. According to a first aspect related to the innovations herein, provided is an image capturing apparatus comprising an image capturing element including photoelectric converting elements that are arranged two-dimensionally and photoelectrically convert incident light into an electrical signal, and an aperture mask including apertures provided to correspond one-to-one with the photoelectric converting elements and positioned in a manner to pass light from different partial regions in a cross-sectional region of the incident light, and a diaphragm that changes shape while maintaining a state in which width of a diaphragm aperture in an arrangement direction of the different partial regions is greater than width of the diaphragm aperture in a direction orthogonal to the arrangement direction.

The summary clause does not necessarily describe all necessary features of the embodiments of the present invention. The present invention may also be a sub-combination of the features described above.

### BRIEF DESCRIPTION OF THE DRAWINGS

FIG. 1 shows a configuration of a digital camera 10 according to an embodiment of the present invention.

FIG. 2A is a cross-sectional schematic view of the image capturing element 100.

FIG. 2B is a cross-sectional schematic view of the image capturing element 120.

FIG. 3 is a schematic view showing a magnified portion of the image capturing element 100.

FIG. 4A is a schematic view for describing the relationship between the subject and the parallax pixels.

FIG. 4B is a schematic view for describing the relationship between the subject and the parallax pixels.

FIG. 4C is a schematic view for describing the relationship between the subject and the parallax pixels.

FIG. 5 is a perspective diagram for describing the process of generating a parallax image.

FIG. 6A shows another exemplary repeating pattern 110.

FIG. 6B shows another exemplary repeating pattern 110.

FIG. 7 shows exemplary repeating patterns arranged two-dimensionally 110.

FIG. 8 is a view for describing another shape of the aperture 104.

FIG. 9 is a view for describing the Bayer arrangement.

FIG. 10 is a view for describing a variation in a case where there are two types of parallax pixels.

FIG. 11 shows an exemplary variation.

FIG. 12 shows another exemplary variation.

FIG. 13 shows yet another exemplar variation.

FIG. 14 is a view for describing another color filter arrangement.

FIG. 15 shows an exemplary arrangement of W pixels and parallax pixels.

FIG. 16 is a front view for describing the diaphragm 50 in a fully open state,

FIG. 17 is a front view for describing the diaphragm 50 in a contracted state.

FIG. 18A is a planar view for describing the parallax amount of the diaphragm 50 in a fully open state.

FIG. 18B is a front view for describing the parallax amount of the diaphragm 50 in a fully open state.

FIG. 19A is a planar view for describing the parallax amount of the diaphragm 50 in a contracted state.

FIG. 19B is a front view for describing the parallax amount of the diaphragm 50 in a contracted state.

FIG. 20A is a planar view for describing the parallax amount of the diaphragm 50 in a contracted state.

FIG. 20B is a front view for describing the parallax amount of the diaphragm 50 in a contracted state.

FIG. 21 is a front view for describing another diaphragm 150 in the fully open state.

FIG. 22 is a front view for describing the diaphragm 150 of FIG. 21 in the contracted state.

FIG. 23 is a front view for describing another diaphragm 250 in the fully open state.

FIG. 24 is a front view for describing the diaphragm 250 of FIG. 23 in the contracted state.

FIG. 25 is a front view for describing another diaphragm 350 in the fully open state.

### DESCRIPTION OF EXEMPLARY EMBODIMENTS

Hereinafter, some embodiments of the present invention will be described. The embodiments do not limit the invention according to the claims, and all the combinations of the features described in the embodiments are not necessarily essential to means provided by aspects of the invention.

A digital camera according to the present embodiment, which is one aspect of an image capturing apparatus, captures images from a plurality of view points with a single image capturing optical system, and saves these images as a RAW image data set. The image having viewpoints that diner from each other is referred to as a “parallax image.”

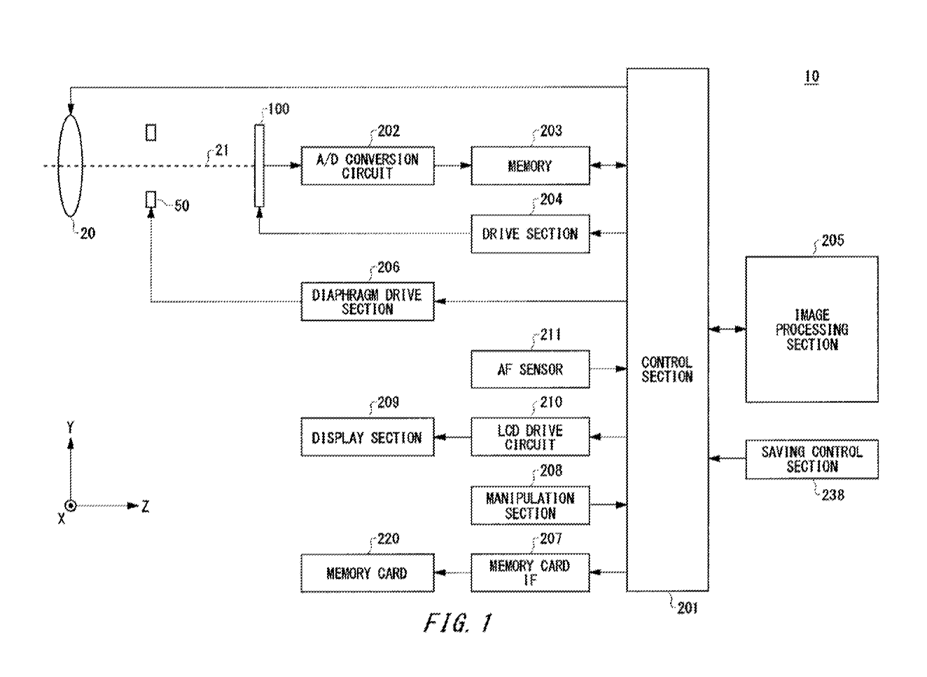

FIG. 1 shows a configuration of a digital camera 10 according to an embodiment of the present invention. The digital camera 10 includes an image capturing lens 20 and a diaphragm 50 as an image capturing optical system. The image capturing lens 20 guides incident subject light along an optical axis 21 to the image capturing element 100. The diaphragm 50 changes the amount of incident light, which is the subject light, by changing the size of an opening with a variable area. The diaphragm 50 is arranged at or near a position conjugate to the position of the pupil of the image capturing lens 20. The image capturing lens 20 may be an exchangeable lens that can be attached along with the diaphragm 50 to the digital camera 10. The digital camera 10 includes the image capturing element 100, a control section 201, an AID conversion circuit 202, a memory 203, a drive section 204, a diaphragm drive section 206 for controlling the diaphragm 50, an image processing section 205, a memory card IF 207, a manipulation section 208, a display section 209, an LCD drive circuit 210, an AF sensor 211, and a storage control section 238.

As shown in FIG. 1, a direction parallel to the optical axis 21 toward the image capturing element 100 is defined as the +Z axis direction, a direction orthogonal to the plane of the Z-axis and moving upward from the plane of the drawing is defined as the +X direction, and a direction upward within the plane of the drawing is defined as the +Y direction. In several of the following drawings, the coordinate axes of FIG. 1 are used as a reference to display the orientation of the drawings on coordinate axes.

The image capturing lens 20 is formed by a plurality of optical lens groups, and focuses the subject light near a focal plane thereof In FIG. 1, for ease of explanation, the image capturing lens 20 is represented by a single virtual lens arranged near the pupil. The image capturing element 100 is arranged near the focal plane of the image capturing lens 20. The image capturing element 100 is an image sensor, such as a CCD or CMOS sensor, in which a plurality of photoelectric converting elements are arranged two-dimensionally. The timing of the image capturing element 100 is controlled by the drive section 204, and the image capturing element 100 converts a subject image focused on a light receiving surface into an image signal and outputs the image signal to the A/D conversion circuit 202.

The A/D conversion circuit 202 converts the image signal output by the image capturing element 100 into a digital signal, and outputs the digital signal to the memory 203 as the RAW image data. The image processing section 205 performs various types of image processing using the memory 203 as a work space, to generate image data.

The image processing section 205 fulfills the general functions of image processing, such as adjusting image data according to other selected image formats. The generated image data is convened into a display signal by the LCD drive circuit 210, and displayed in the display section 209. Each type of image data is recorded in the memory card 220 attached to the memory card IF 207 by the storage control section 238.

The AF sensor 211 is a phase sensor having a plurality of distance measurement points set for a subject space, and detects the defocus amount of a subject image at each distance measurement point. An image capturing, sequence is begun in response to the user manipulation the manipulation section 208 and a manipulation signal being output to the control section 201. The various operations, such as AF and AE, associated with the image capturing sequence are executed under the control of the control section 201. For example, the control section 201 analyzes the detection signal of the AF sensor 211 and executes focus control to move a focus lens, which is a portion of the image capturing lens 20. The parallax pixels discussed below may be configured to share functions of the AF sensor 211. In this case, the AF sensor 211 can be omitted.

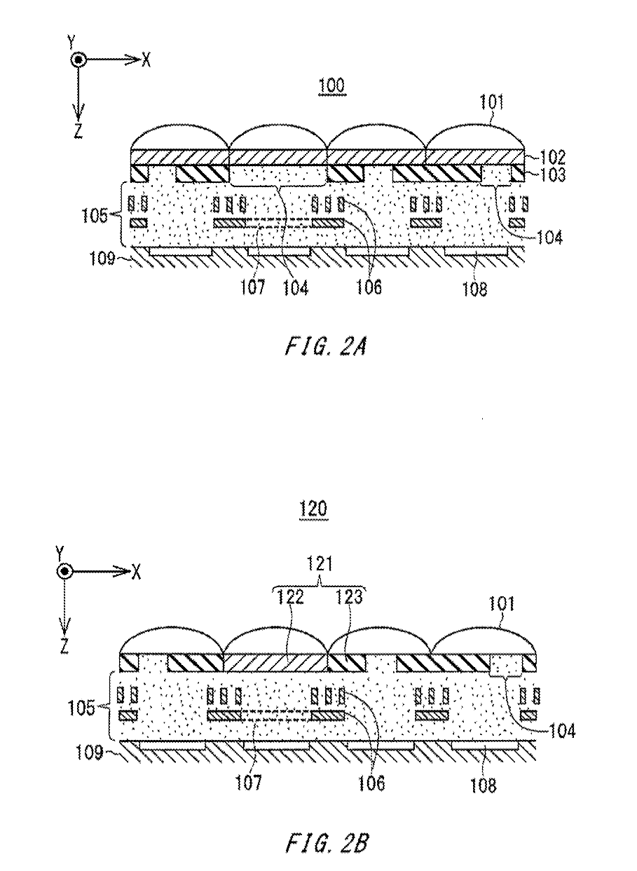

The following describes a configuration of the image capturing element 100. FIG. 2A is a schematic view showing a cross section of the image capturing element 100 in which the color filter 102 and the aperture mask 103 are separate structures. FIG. 2B is a schematic view showing a cross section of the image capturing element 120 according to a modification of the image capturing element 100, including a screen filter 121 in which the color filter 122 and the aperture mask 123 are formed integrally.

As shown in FIG. 2A, the image capturing element 100 is formed by arranging microlenses 101, color filters 102, aperture masks 103, a wiring layer 105, and photoelectric converting elements 108 in the stated order from the subject side. The photoelectric converting elements 108 are each formed by a photodiode that converts incident light into an electrical signal. A plurality of the photoelectric converting elements 108 are arranged two-dimensionally on the surface of a substrate 109.

The image signals resulting from the conversion by the photoelectric converting elements 108 and the control signals for controlling the photoelectric converting elements 108, for example, are transmitted and received by wiring 106 provided in the wiring layer 105. Each aperture mask 103 of the apertures 104 corresponding one-to-one with the photoelectric converting elements 108 and arranged repeatedly in two dimensions is in contact with the wiring layer. The color filter 102 and the aperture mask 103, which has parallax characteristics, are layered on the same photoelectric converting element 108. As described further below, the apertures 104 are strictly positioned at locations shifted relative to the corresponding photoelectric converting elements 108. The specifics are described further below, but the aperture masks 103 having the apertures 104 function to create parallaxes in the subject light received by the photoelectric converting elements 108.

There are no aperture masks 103 provided for photoelectric converting elements 108 that do not cause a parallax. In other words, it could also be said that there are aperture masks 103 including apertures 104 that pass all effective light, i.e., that do not limit the subject light incident to the corresponding photoelectric converting elements 108. Although no parallax is caused, the aperture 107 formed by the wiring 106 substantially determines the incident subject light, and therefore the wiring 106 can be thought of as an aperture mask that passes all effective light and does not cause a parallax. The aperture 107 may be formed on the wiring 106 which is the top layer of the wiring layer 105. Each aperture mask 103 may be arranged independently in correspondence with a photoelectric converting element 108, or the aperture masks 103 may be formed en bloc for a plurality of photoelectric converting elements 108 using the same manufacturing process as used for the color filters 102.

The color filters 102 are provided on the aperture masks 103. The color filters 102 correspond one-to-one with the photoelectric converting elements 108, and each color filter 102 is colored to pass a specified wavelength band to the corresponding photoelectric converting element 108. In order to output a color image, it is only necessary to arrange three different types of color filters. These color filters can be referred to as primary color filters for generating a color image. A combination of primary color filters includes, for example, a red filter that passes a red wavelength band, a green filter that passes a green wavelength band, and a blue filter that passes a blue wavelength band. These color filters are arranged in a grid according to the photoelectric converting elements 108, as described further below. The color filters are not limited to a primary color combination of RGB, and a combination of YeCyMg complementary color filters may be used.

The microlenses 101 are provided on the color filters 102. Each microlens 101 is a converging lens that guides a majority of the subject light incident thereto to the corresponding photoelectric converting element 108. The microlenses 101 correspond one-to-one with the photoelectric converting elements 108. Each microlens 101 preferably has the optical axis thereof shifted to guide more subject light to the corresponding photoelectric converting element 108, with consideration to the relative positions of the center of the image capturing lens 20 and the corresponding photoelectric converting element 108. Furthermore, in addition to adjusting the positioning of the aperture masks 103 of the apertures 104, the positioning of the microlenses 101 may be adjusted such that more of the specified subject light described further below, is incident.

In this way, the single unit of an aperture mask 103, a color filter 102 and a microlens 101 provided one-to-one for each photoelectric converting, element 108 is referred to as a “pixel.” More specifically, a pixel including an aperture mask 103 that causes a parallax is referred to as a “parallax pixel,” and a pixel including an aperture mask 103 that does not cause a parallax is referred to as a “non-parallax pixel.” If the effective pixel region of the image capturing element 100 is approximately 24 mm by 16 mm, there may be approximately 12 million pixels, for example.

If the image sensor has good collection efficiency and photoelectric conversion efficiency, the microlenses 101 need not be provided. If a back-illuminated image sensor is used the wiring layer 105 is provided on the opposite side of the photoelectric converting elements 108.

There are a many variations resulting from the combination of a color filter 102 and an aperture mask 103. In FIG. 2A, if the apertures 104 of the aperture masks 103 have a color component, the color filters 102 and the aperture masks 103 can be formed integrally. Furthermore, when a certain pixel is set as a pixel for acquiring brightness information of the subject, this pixel need not be provided with a corresponding color filter 102. As another option, a transparent filter may be provided that is not colored, such that the wavelength band of almost all visible light is passed.

When setting a pixel that acquires brightness information as a parallax pixel, i.e. when the parallax image is output at least once as a monochromatic image, the configuration of the image capturing element 120 shown in FIG. 2B can be adopted. In other words, the screen filter 121 in which the color filter section 122 functioning as the color filter and the screen filter 121 with the aperture mask section 123 having the aperture 104 are formed integrally can be provided between the microlens 101 and the wiring layer 105.

In the screen filter 121, the color filter section 122 is colored with red, green, and blue, for example, and the mask portion of the aperture mask section 123 other than the aperture 104 is colored black. Compared to the image capturing element 100, the image capturing element 120 adopting the screen filter 121 has a shorter distance from the microlens 101 to the photoelectric converting element 108, and therefore has higher light gathering efficiency for the subject light.

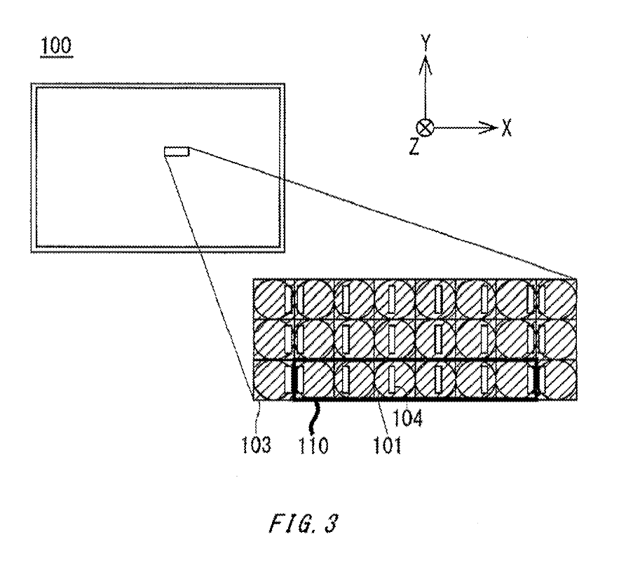

The following describes the relationship between the apertures 104 of the aperture masks 103 and the resulting parallaxes. FIG. 3 is a schematic view showing a magnified portion of the image capturing element 100. For ease of explanation, the color arrangement of the color filters 102 is not discussed at this point, and is instead brought up later. In the following description that does not deal with coloring of the color filters 102, it can be assumed that the image sensor is formed by gathering together only parallax pixels having color filters 102 of the same color (including transparency). Accordingly, the repeating pattern described below may be thought of as adjacent pixels in color filters 102 of the same color.

As shown in FIG. 3, the apertures 104 of the aperture masks 103 are shifted relative to the pixels. In adjacent pixels, the apertures 104 are located at different positions.

In the example of FIG. 3, there are six types of aperture masks 103 in which the apertures 104 are shifted to different positions on the X-axis with respect to the pixels. The overall image capturing element 100 is formed by periodically and two-dimensionally arranging groups of photoelectric converting elements including six sets of parallax pixels having aperture masks 103 that are gradually shifted from the −X side to the +X side in FIG. 3. In other words, in the image capturing element 100, repeating patterns 110 that each include one group of photoelectric, converting elements are packed together periodically.

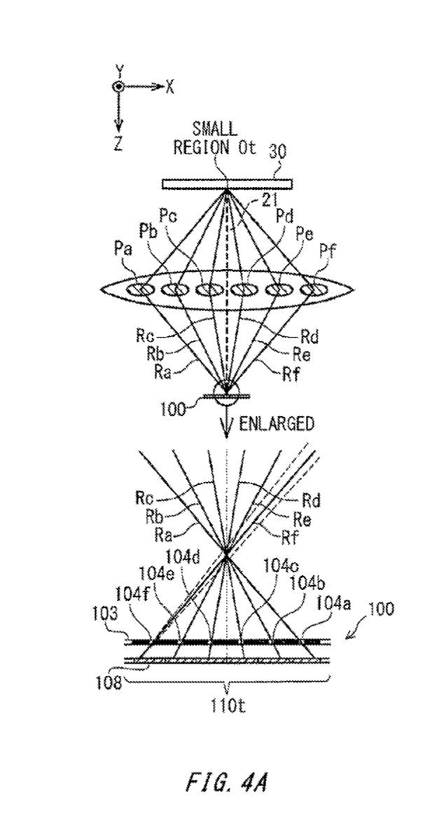

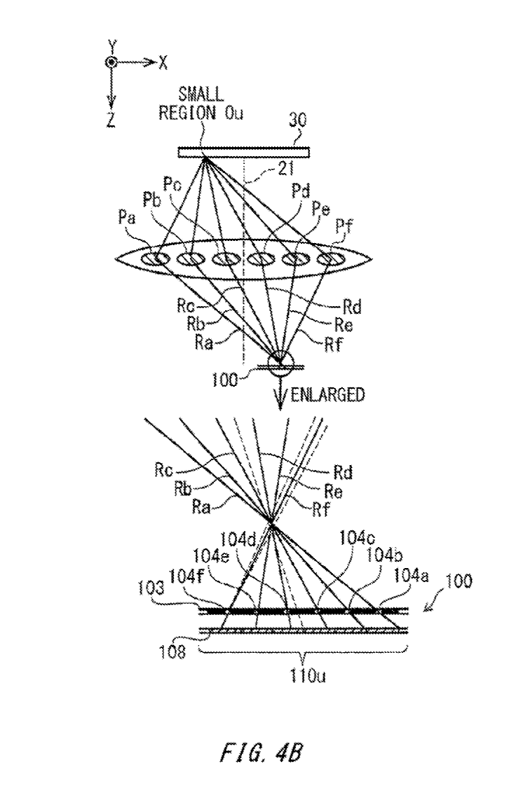

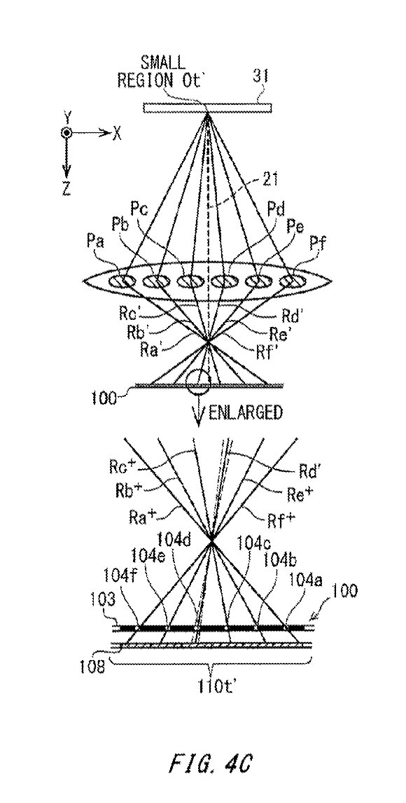

FIG. 4A is a schematic, view for describing the relationship between the subject and the parallax pixels in the photoelectric converting elements of the repeating, pattern 110t arranged in the center of the image capturing element 100 orthogonal to the optical axis 21 for image capturing. FIG. 4B is a schematic view for describing the relationship between the subject and the parallax pixels in the photoelectric converting elements of the repeating pattern 110u arranged in the peripheral region. The subject 30 in FIGS. 4A and 4B is at a focal position of the image capturing lens 20. FIG. 4C corresponds to FIG. 4A and schematically shows the relationship in a case where the subject is at a non-focal position of the image capturing lens 20.

The following describes the relationship between the parallax pixels and the subject when the image capturing lens 20 captures a subject 30 in a focused state. The subject light passes through the pupil of the image capturing lens 20 and is guided to the image capturing element 100, and six partial regions Pa to Pf are defined in the overall cross-sectional region through which the subject light passes. As shown in the magnified portion as well, the position of the aperture 104f of the aperture mask 103 is set such that the pixels at the −X edges of the photoelectric converting element groups forming the repeating patterns 110t and 110u cause only the subject light emitted from the partial region Pt to reach the photoelectric converting element 108. Progressing to pixels closer to the +X edge, the position of the aperture 104e corresponding to the partial region Pe, the position of the aperture 104d corresponding to the partial region Pd, the position of the aperture 104c corresponding to the partial region Pc, the position of the aperture 104b corresponding to the partial region Pb, and the position of the aperture 104a corresponding to the partial region Pa are each determined in the sane manner.

In other words, the inclination of the primary light ray Rf of the subject light emitted from the partial region PC which is determined according to the relative position of the −X edge pixel with respect to the partial region Pf, for example, can be said to determine the position of the aperture 104f. When the photoelectric converting element 108 receives the subject light from the subject 30 at the focused position via the aperture 104f, the subject light is focused on the photoelectric converting element 108 as shown by the dashed lines. Similarly, for pixels further toward the +X edge, the position of the aperture 104e is determined by the inclination of the primary light ray Re, the position of the aperture 104d is determined by the inclination of the primary light ray Rd, the position of the aperture 104c is determined by the inclination of the primary light ray Rc, the position of the aperture 104b is determined by the inclination of the primary light ray Rb, and the position of the aperture 104a is determined by the inclination of the primary light ray Ra.

As shown in FIG. 4A, the light emitted from the small region Ot of the subject 30 orthogonal to the optical axis 21 and located at the focused position passes through the pupil of the image capturing lens 20 to arrive at each of the pixels in the photoelectric converting element group that forms the repeating pattern 110t. More specifically, the pixels of the photoelectric converting element group that forms the repeating pattern 110t each receive light emitted from the one small region Ot, respectively through the six partial regions Pa to Pf. The small region Ot widens by an amount corresponding to the positional shift of each pixel of the photoelectric converting element group that forms the repeating pattern 110t, but can substantially approximate an object point that is substantially the same. Similarly, as shown in FIG. 4B, the light emitted from the small region Ou of the subject 30 distanced from the optical axis 21 and located at the focused position passes through the pupil of the image capturing lens 20 to arrive at each of the pixels in the photoelectric converting element group that forms the repeating pattern 110u. More specifically, the pixels of the photoelectric converting element group that forms the repeating pattern 110u each receive light emitted from the one small region Ou, respectively through the six partial regions Pa to Pf. In the same manner is the small region Ot, the small region Ou widens by an amount corresponding to the positional shift of each pixel of the photoelectric converting element group that forms the repeating pattern 110t, but can substantially approximate an object point that is substantially the same.

In other words, as long as the subject 30 is located at the focused position, the small region captured by the photoelectric converting element group differs according to the position of the repeating pattern 110 on the image capturing element 100, and each pixel in the photoelectric converting element group captures the same small region via a different partial region. Corresponding pixels in each repeating pattern 110 receive subject light from the same partial region. In other words, in the drawings, the pixels at the −X edges of the repeating patterns 110t and 110u each receive subject light from the same partial region Pf.

Strictly speaking, the position of the aperture 104f through which the −X edge pixel in the repeating pattern 110t arranged orthogonal to the image capturing optical axis 21 at the center thereof receives the subject light from the partial region Pf differs from the position of the aperture 104f through which the −X edge pixel in the repeating pattern 110u arranged at the periphery of the image capturing optical axis receives the subject light from the partial region Pf. However, from a functional point of view, these aperture masks can be treated as being the same type with respect to receiving subject light from the partial region Pf. Accordingly, in the examples of FIGS. 4A, 4B, and 4C each of the parallax pixels arranged on the image capturing element 100 can be considered as having one of six types of aperture masks.

The following describes the relationship between the parallax pixels and the subject when the image capturing lens 20 captures the subject 31 in an unfocused state. In this case as well, the subject light from the subject 31 located at an unfocused position passes through the six partial regions Pa to Pf of the pupil of the image capturing lens 20 to arrive at the image capturing element 100. It should be noted that the subject light from the subject 31 at the unfocused position converges at a position that is not on the photoelectric converting element 108. For example, as shown in FIG. 4C, when the subject 31 is further from the image capturing element 100 than the subject 30, the subject light converges on the subject 31 side of the photoelectric converting element 108. Inversely, when the subject 31 is closer to the image capturing element 100 than the subject 30, the subject light converges on a side of the photoelectric converting element 108 opposite the subject 31.

Accordingly, the subject light emitted from a small region Ot′ of the subject 31 located at the unfocused position arrives at corresponding pixels of different repeating patterns 110 depending on Which of the six partial regions Pa to Pf the subject light passes through. For example, as shown in FIG. 4C, the subject light that passes through the partial region Pd is a primary light ray Rd′ incident to the photoelectric converting element 108 having that aperture 104d included in the repeating pattern 110t′. Among the subject light emitted from the small region Ot′, the subject light passing through another partial region is not incident to a photoelectric converting element 108 included in the repeating pattern 110t′, and is instead incident to a photoelectric converting element 108 having an aperture corresponding to another repeating pattern. In other words, the subject light arriving at each of the photoelectric converting elements 108 forming the repeating pattern 110t′ is respectively emitted from different small regions of the subject 31. Specifically, subject light in which the primary light ray is Rd′ is incident to the 108 corresponding to the aperture 104d, and a plurality of types of subject light in which the primary light rays are respectively Ra⁺, Rb⁺, Rc⁺, Re⁺, and Rf⁺ are input to the corresponding photoelectric converting elements 108 of other apertures. Each of these types of subject light is emitted from a different small region of the subject 31. This relationship is the same in the repeating pattern 110u arranged in the peripheral region shown in FIG. 4B.

Therefore, when viewed with the entire image capturing element 100, the subject image A captured by the photoelectric converting element 108 corresponding to the aperture 104a and the subject image D captured by the photoelectric converting element 108 corresponding to the aperture 104d, for example, do not have a skew therebetween when the subject is at the focused position and do have a skew therebetween when the subject is at an unfocused position. The amount and direction of this skew depend on the distance between the partial region Pa and the partial region Pd and on which direction the subject at the unfocused position is located with respect to the focused position. In other words, the subject image A and the subject image D are parallax images with respect to each other. This relationship is the same for each of the other apertures, and therefore six parallax images are formed corresponding to the apertures 104a to 104f. Furthermore, the different arrangement directions of the partial regions Pa to Pf are referred to as the “parallax direction.” In this example, the parallax, direction is along the X axis.

Accordingly, when the outputs of corresponding pixels in each of the repeating patterns 110 formed in this way are gathered, a parallax image is obtained. Specifically, the outputs of the pixels that receive the subject light, emitted from a prescribed partial region among the six partial regions Pa to Pf form a parallax image. As a result, a single image capturing lens 20 can be used to capture the parallax image with the different arrangement directions of the partial regions Pa to Pf serving as the parallax direction, without requiring a complicated optical system.

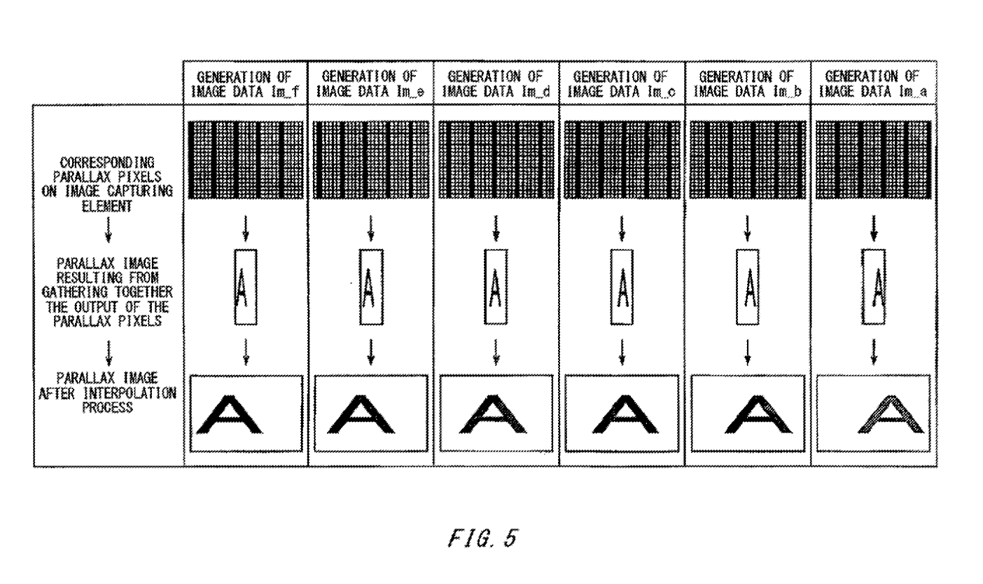

FIG. 5 is a schematic view for describing the process of generating parallax images. FIG. 5 shows, from left to right in the plane of the drawing, generation of parallax image data Im_f generated by gathering the outputs of the parallax pixels corresponding to the apertures 104f, generation of parallax image data Im_e resulting from the outputs of the apertures 104e, generation of parallax image data Im_d resulting from the outputs of the apertures 104d, generation of parallax image data Im_c resulting from the outputs of the apertures 104c, generation of parallax image data Im_b resulting from the outputs of the apertures 104b, and generation of parallax image data Im_a resulting from the outputs of the apertures 104a. First, generation of the parallax image data Im_resulting from the outputs of the apertures 104f will be described.

The repeating patterns 110 formed respectively by groups of photoelectric converting elements including a set of six parallax pixels are arranged in horizontal lines, which are in a direction parallel to the X axis. Accordingly, the parallax pixels of the apertures 104f are every sixth pixel in the X axis direction on the image capturing element 100, and are adjacent in series in the Y axis direction. Each of these pixels receives subject light from a different small region, in the manner described above. Accordingly, a parallax image in the X axis direction, i.e. the horizontal direction, can be obtained by gathering and arranging the outputs of these parallax pixels.

However, since each pixel of the image capturing element 100 according to the present embodiment is square, merely gathering the pixels together results in these pixels being thinned to one of every six pixels in the X axis direction, and the generated image data is therefore stretched in the Y axis direction. Therefore, the parallax image data Im_f is generated as an image with a conventional aspect ratio by performing interpolation to obtain six times the number of pixels in the X axis direction. It should be noted that the parallax image data prior to the interpolation is an image thinned to ⅙ in the X axis direction, and therefore the resolution in the X axis direction is lower than the resolution in the Y axis direction. In other words, the number of pieces of parallax image data generated has an inverse relationship with improvement of the resolution.

In the same manner, parallax image data Im_e to parallax image data. Im_a is obtained. In other words, the digital camera 10 can generate a horizontal parallax image with six points having a parallax in the X axis direction.

In the above example, rows in the X axis direction are arranged periodically as the repeating patterns 110, but the repeating patterns 110 are not limited to this.

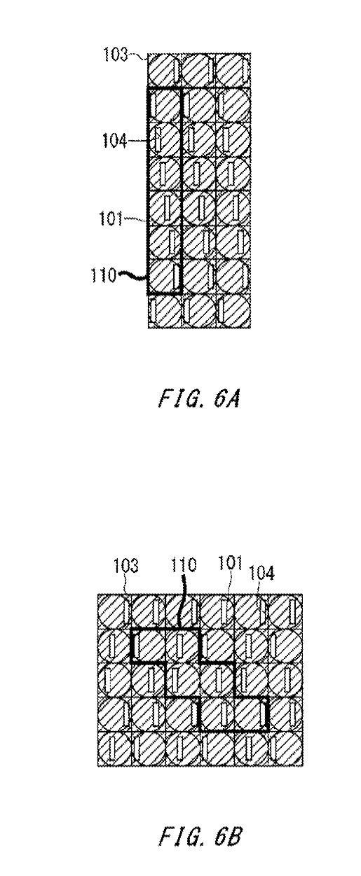

FIG. 6A shows an exemplar repeating pattern 110 in which six pixels are arranged in the Y as direction, Here, the position of each aperture 104 is gradually shifted from the −X side toward the +X side, in a direction from the parallax pixel at the +Y edge toward the −Y edge. The repeating patterns 110 arranged in this way can also generate parallax images from six view points having parallaxes in the X axis direction therebetween. Compared to the repeating pattern 110 of FIG. 3, this repeating pattern maintains the X axis direction resolution in exchange for sacrificing the Y axis direction resolution.

FIG. 6B shows an exemplary repeating pattern 110 in which six pixels are arranged adjacent to each other in a diagonal direction. The position of each aperture 104 is gradually shifted from the −X side to the +X side, in a direction from the parallax pixel at the −X and +Y corner to the parallax pixel at the +X and −Y corner. The repeating patterns 110 arranged in this way can also generate parallax images with six view points having X axis direction parallaxes therebetween. Compared to the repeating pattern 110 of FIG. 3, this repeating pattern can increase the number of parallax images while maintaining both the X axis direction and Y axis direction resolution to a certain degree.

In a comparison between the repeating patterns 110 of FIGS. 3, 6A, and 6B, when generating parallax images with six view points, each repeating pattern 110 differs by sacrificing either Y axis direction resolution or X axis direction resolution with respect to the resolution obtained when outputting one image that is not a parallax image from an arrangement that is entirely non-parallax pixels. When the repeating pattern 110 of FIG. 3 is used, the X axis direction resolution becomes ⅙. When the repeating pattern 110 of FIG. 6A is used, the Y axis direction resolution becomes ⅙. When the repeating pattern 110 of FIG. 6B is used, the Y axis direction resolution becomes ⅓ and the X axis direction resolution becomes ½. In each case, one of each of the apertures 104a to 104f corresponding to the pixels is provided in each pattern, and the subject light is received from each of the corresponding partial regions Pa to Pf. Accordingly, the parallax amount is the same for each repeating pattern 110.

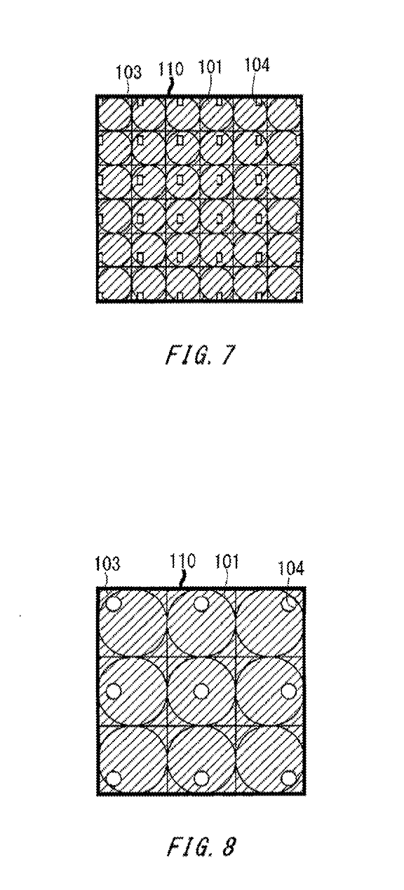

The above describes an example of generating parallax images with a parallax in the horizontal direction, but it is obvious that parallax images having to parallax in the vertical direction or parallax images having a two-dimensional parallax in both the horizontal and vertical directions can be generated. FIG. 7 shows an exemplary two-dimensional repeating pattern 110.

The exemplary repeating pattern 110 of FIG. 7 includes, as a photoelectric converting element group, 36 pixels in an arrangement of six pixels in the Y axis direction by six pixels in the X axis direction. The position of the aperture 104 relative to each pixel is shifted in both the Y axis and X axis directions to be different for each pixel, thereby forming 36 types of aperture masks 103. Specifically, the apertures 104 are gradually shifted from the +Y side to the −Y side in a direction from the +Y edge of pixels to the −Y edge of pixels of the repeating pattern 110, and gradually shifted from the −X side to the +X side in a direction from the −X edge of pixels to the +X edge of pixels.

The image capturing element 100 including such a repeating pattern 110 can output parallax images with 36 view points having parallaxes in both the horizontal and vertical directions. It is obvious that the arrangement is not limited to the example of FIG. 7, and the repeating pattern 110 can be set to output parallax images with various numbers of view points.

In the above description, the apertures 104 are rectangles. In particular, in an arrangement for creating a horizontal parallax, the amount of light guided to the photoelectric converting elements 108 can be ensured by setting the width of the apertures 104 in the direction of the shifting, which is the X axis direction, to be less than the width in the direction in which there is no shifting, which is the Y axis direction. However, the apertures 104 are not limited to having a rectangular shape.

FIG. 8 shows an example of apertures 104 having other shapes. In FIG. 8, the apertures 104 are circular. When circular apertures 104 are used, unintended subject light can be prevented from becoming stray light and being incident to the photoelectric converting elements 108, due to the relationship with the semi circular microlenses 101.

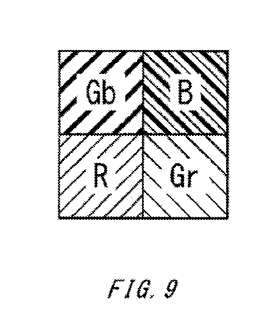

The following describes a parallax image for a color filter 102. FIG. 9 is used to describe a Bayer arrangement. As shown in FIG. 9, in the Bayer arrangement, green filters are allocated to the two pixels in the −X and +Y corner and in the +X and −Y corner, a red filter is allocated to the pixel in the −X and −Y corner, and a blue filter is allocated to the pixel in the +X and +Y corner. Here, the pixel in the +X and −Y corner to which a green filter is allocated is referred to as a Gb pixel, and the pixel in the −X and +Y corner to which a green filter is allocated is referred to as a Gr pixel. The pixel to which the red filter is allocated is referred to as an R pixel, and the pixel to which the blue filter is allocated is referred to as a B pixel. The X axis direction in which the Gb pixel and the B pixel are lined up is referred to as the Gb row, and the X axis direction in which the R pixel and the Gr pixel are lined up is referred to as the Gr row. The Y axis direction in which the Gb pixel and the R pixel are lined up is referred to as the Gb column, and the Y axis direction in which the B pixel and the Gr pixel are lined up is refined to as the Gr column.

With this color filter 102 arrangement, a large number of repeating patterns 110 can be set by allocating parallax pixels and non-parallax pixels with various colors at various intervals. By gathering the outputs of non-parallax pixels, non-parallax image data can be generated in the same mariner as a normal captured image. Accordingly, if the ratio of non-parallax pixels is increased, a 2D image with high resolution can be output. In this case, the ratio of parallax pixels is relatively low, and therefore the amount of stereoscopic information as it 3D image formed by it plurality of parallax images is reduced. On the other hand, if the ratio of parallax pixels is increased, the amount of stereoscopic information as a 3D image is increased, but the number of non-parallax pixels is decreased, and therefore a 2D image with low resolution is output.

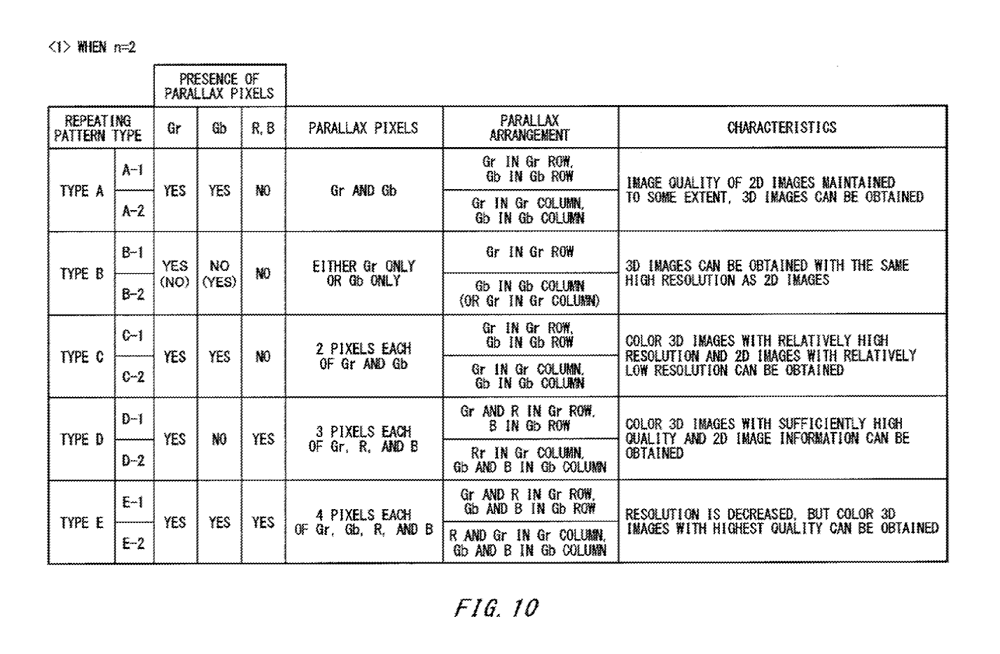

With this tradeoff relationship, repeating patterns 110 can be set to have a variety of characteristics by determining which pixels are parallax pixels and which are non-parallax pixels. FIG. 10 describes variations for the allocation of parallax pixels in the Bayer arrangement in which there are two types of parallax pixels. In this case, it is assumed that the parallax pixels are a parallax Li pixel that is centered to the −X side of the center of the aperture 104 and a parallax Rt pixel that is centered to the +X side of the center of the aperture 104. In other words, the parallax image with two view points output from these parallax pixels has a so-called stereoscopic appearance.

The characteristics for each repeating pattern are as described in FIG. 10. For example, 2D image data with high resolution is obtained when a large number of non-parallax pixels are allocated, and 2D image data with high image quality and low color drift is obtained when the non-parallax pixels are allocated uniformly among the red, green, and blue pixels. On the other hand, when a large number of parallax pixels are allocated, the resulting 3D image data contains a large amount of stereoscopic information, and if red, green, and blue pixels are allocated uniformly, high quality color image data is realized while maintaining the 3D image.

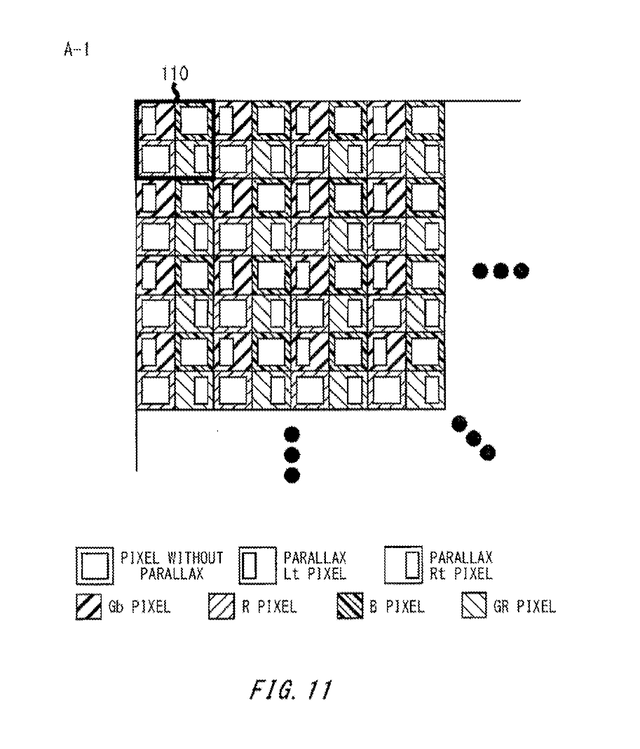

The following describes several variations. FIG. 11 shows an exemplary variation. The variation of FIG. 11 corresponds to the repeating pattern type A-1 in FIG. 10.

In the example of FIG. 11, a four-pixel set that is the same as the Bayer arrangement is set as the repeating pattern 110. The R pixels and the B pixels are non-parallax pixels, the Gb pixels are allocated as parallax Lt pixels, and the Gr pixels are allocated as parallax Rt pixels. In this case, the parallax Lt pixel and parallax Rt pixel included in the same repeating pattern 110 have apertures 104 that are set to receive light emitted from the same small region when the subject is at a focal position.

In the example of FIG. 11, the Gb pixels and Gr pixels, which are green pixels having high visual sensitivity, at used as the parallax pixels, and therefore the acquired image is expected to have high contrast. Furthermore, since the Gb pixels and the Gr pixels used as the parallax pixels are the same color, the computation for converting the output of the two pixels into an output without a parallax is simple, and together with the output of the R pixels and B pixels, which are the non-parallax pixels, 2D image data with high quality can be generated.

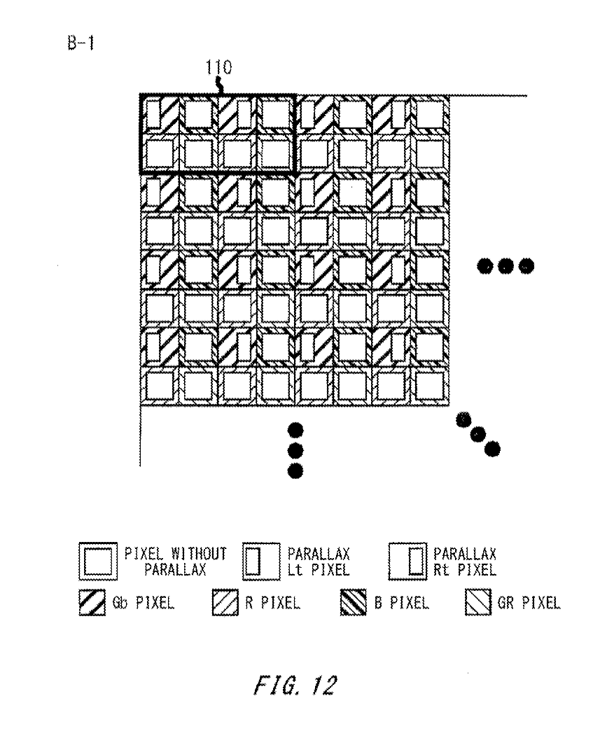

FIG. 12 shows another exemplary variation. The variation shown in FIG. 12 corresponds to the B-1 type of repeating pattern of FIG. 10,

In the example of FIG. 12, the repeating pattern 110 is formed by eight pixels resulting from two sets of the four-pixel Bayer arrangement being placed adjacently in the X axis direction. Among these eight pixels, the parallax Lt pixel is allocated to the Gb pixel on the +X side and the parallax Rt pixel is allocated to the Gb pixel on the −X side. With this arrangement, the quality of a 2D image can be increased beyond that of the example shown in FIG. 10, by setting the Gr pixels to be non-parallax pixels.

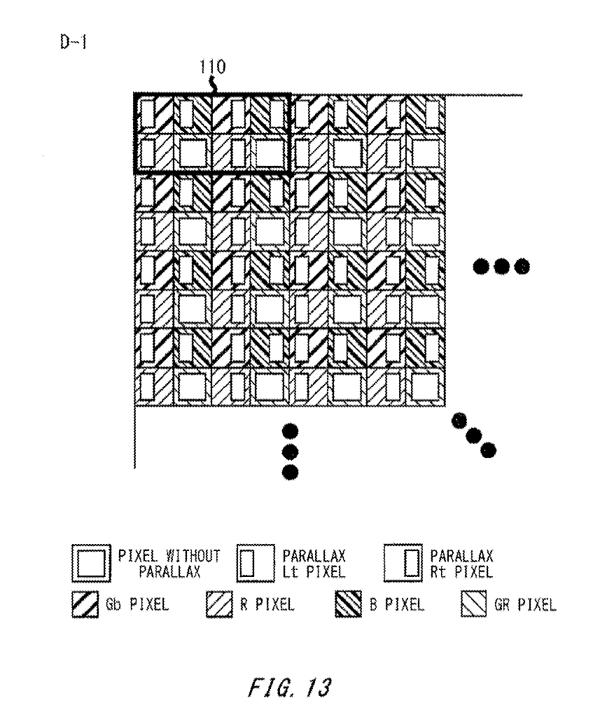

FIG. 13 shows another exemplary variation, The variation shown in FIG. 13 corresponds to the D-1 type of repeating pattern of FIG. 10.

In the example of FIG. 13, the repeating pattern 110 is formed by eight pixels resulting from two sets of the four-pixel Bayer arrangement being placed adjacently in the X axis direction. Among these eight pixels, a parallax Lt pixel is allocated to the Gb pixel on the −X side and a parallax Rt pixel is allocated to the Gb pixel on the +X side. Furthermore, a parallax Lt pixel is allocated to the R pixel on the −X side, and a parallax Rt pixel is allocated to the R pixel on the +X side. Yet further, a parallax Lt pixel is allocated to the B pixel on the −X side, and a parallax Rt pixel is allocated to the B pixel on the +X side. Non-parallax pixels are allocated to the two Gr pixels.

The parallax Lt pixel and parallax Rt pixel allocated to the two Gb pixels receive light emitted from the same small region when the subject is at the focused position. The parallax Lt pixel and the parallax Rt pixel allocated to the two R pixels receive light emitted from one small region that is different from the small region corresponding to the Gb pixels, and the parallax Lt pixel and the parallax Rt pixel allocated to the two B pixels receive light emitted from one small region that is different from the small region corresponding to the Gb pixels and the small region corresponding to the R pixels. Accordingly, compared to the example of FIG. 12, the example of FIG. 13 can obtain a 3D image with three times the amount of stereoscopic information for the vertical direction. Furthermore, since the output is obtained in the three colors red, green, and blue, the resulting image is a high-quality 3D color image.

A parallax image with two view points can be obtained using the two types of parallax pixels in the manner described above, but it is obvious that various types of parallax pixels can be adopted, such as described in FIGS. 3, 7, and 8, according to the number of parallax images to be output. Even when the number of view points increases, a variety of repeating patterns 110 can be formed. According, the repeating patterns 110 can be selected according to the specifications, goals, or the like.

In the examples described above, the Bayer arrangement is adopted for the color filter arrangement, but it is obvious that other color filter arrangements can be used without problems. At this time, each parallax pixel forming the photoelectric converting element group may include an aperture mask 103 having an aperture 104 oriented toward a different partial region.

Accordingly, the image capturing element 100 includes photoelectric converting elements 108 that are arranged two-dimensionally and photoelectrically convert incident light into an electrical signal, aperture masks 103 corresponding one-to-one with the at least some of the photoelectric converting elements, and color filters 102 corresponding one-to-one with the at least some of the photoelectric converting elements. Among n (n is an integer of 3 or more) adjacent photoelectric converting elements 108, the apertures 104 of the aperture mask 103 corresponding to at least two of the photoelectric converting elements 108 may be included in one color filter pattern formed by at least three types of color filters 102 that pass different wavelength bands and positioned in a manner to pass light from the different partial regions in the cross-sectional region of the incident light, and a photoelectric converting element group containing n photoelectric converting elements 108 may be arranged periodically.

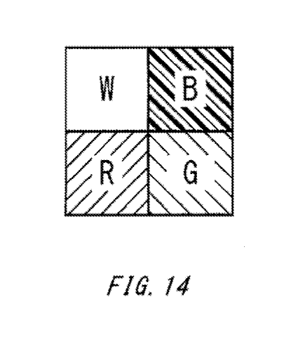

FIG. 14 is used to describe another color filter arrangement. As shown in FIG. 14, in this color filter arrangement, the Gr pixel in the Bayer arrangement shown in FIG. 9 remains as a G pixel to which a green filter is allocated, but the Gb pixel is changed to a W pixel to which no color filter is allocated. The W pixel passes practically the entire wavelength band of visible light, as described above, and may have a transparent filter with no applied color arranged therein.

This color filter arrangement that includes the W pixel causes a small decrease in the accuracy of the color information output by the image capturing element, but the amount of light received by the W pixel is greater than the amount of light received by pixels having color filters, and therefore highly accurate brightness information can be obtained. A monochromatic image can be formed by gathering the output of the W pixels.

When the color filter arrangement including the W pixel is used there are even more variations of repeating patterns 110 including parallax pixels and non-parallax pixels. For example, even if an image is captured in a relatively dark environment, the pixels output a subject image with higher contrast than the image output from color pixels. Therefore, if parallax pixels are allocated to the W pixels, a highly accurate computational result can be expected in an interpolation process performed between a plurality of parallax images. As described further below, the interpolation process is performed as part of the process for acquiring a parallax pd amount. Accordingly, the repeating pattern 110 including parallax pixels and non-parallax pixels is set to affect the quality of the parallax image and the resolution of a 2D image, and in consideration of the advantages and disadvantages with respect to other extracted information.

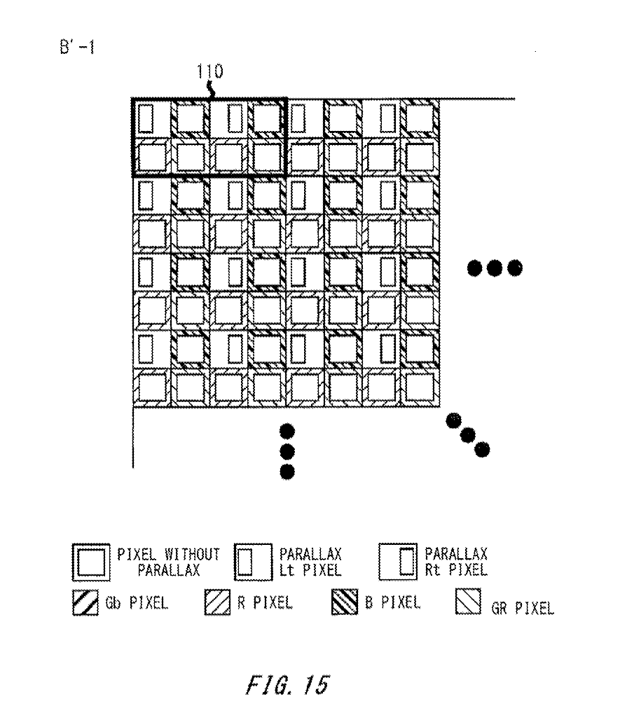

FIG. 15 shows an exemplary arrangement of W pixels and parallax pixels when the color filter arrangement of FIG. 14 is adopted. The variation shown in FIG. 15 resembles the type B-1 repeating pattern of FIG. 12 in the Bayer arrangement, and therefore this variation is labeled as B′-1. In this example, the repeating pattern 110 is formed by eight pixels resulting from two of the four-pixel color filter arrangements being arranged in series in the X axis direction. Among these eight pixels, a parallax Lt pixel is allocated to the W pixel on the −X side and a parallax Rt pixel is allocated to the W pixel on the +X side. With this arrangement, the image capturing element 100 outputs a monochromatic image as the parallax image, and outputs a color image as the 2D image.

In this case, the image capturing element 100 includes photoelectric converting elements 108 that are arranged two-dimensionally and convert incident light into an electrical signal, aperture masks 103 corresponding one-to-one with at least a portion of the photoelectric converting elements 108, and color filters 102 corresponding one-to-one with at least a portion of the photoelectric converting elements 108. Among n adjacent photoelectric converting elements 108, where n is an integer greater than or equal to 4, the apertures 104 of the aperture masks 103 corresponding to at least three of the photoelectric converting elements 108 are not included in the pattern of the color filter pattern formed from at least two types of color filters 102 that pass different wavelength bands and are positioned to respectively pass light from different partial regions within a cross-sectional region of the incident light, and the photoelectric converting element groups each including n photoelectric converting elements 108 are arranged periodically.

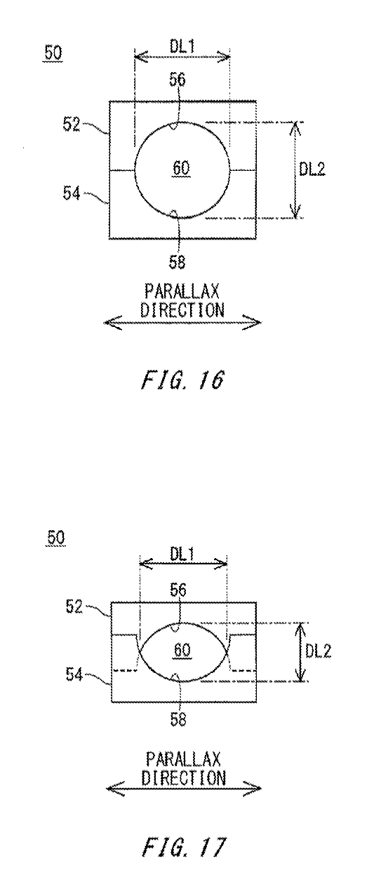

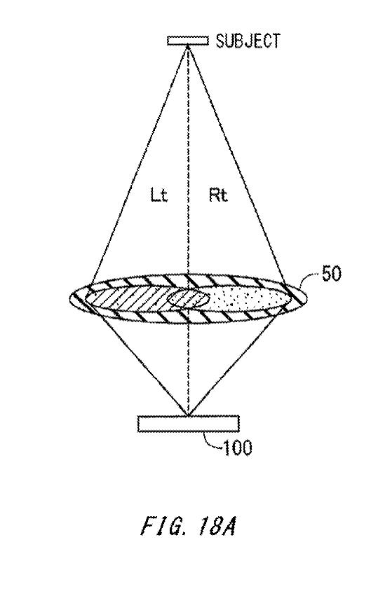

FIG. 16 is a front view for describing the diaphragm 50 in a fully open state. FIG. 17 is a front view for describing the diaphragm 50 in a contracted state. As shown in FIG. 16, the diaphragm 50 includes an upper diaphragm panel 52 and a lower diaphragm panel 54, An upper recess 56, which has a semicircular shape opening downward, is formed on the bottom of the central portion of the upper diaphragm panel 52. The “semicircular” shape is one example of a “partial-circle” shape. The upper diaphragm panel 52 is capable of moving in the vertical direction. A lower recess 58, which has a semicircular shape opening upward, is formed in the top of the central portion of the lower diaphragm panel 54. The lower recess 58 and the upper recess 56 are opposite each other. The lower diaphragm panel 54 is capable of moving vertically. In other words, the upper diaphragm panel 52 and the lower diaphragm panel 54 move relative to each other. The upper diaphragm panel 52 and the lower diaphragm panel 54 may move according to a drive signal input to the diaphragm drive section 206 by the control section 201, or may be moved manually by a user. By arranging the bottom edge of the upper diaphragm panel 52 and the top edge of the lower diaphragm panel 54 at substantially the same position, the upper recess 56 and the lower recess 58 form a substantially circular diaphragm aperture 60 through which light passes.

In the fully open state of the aperture 50 shown in FIG. 16, the diaphragm aperture 60 is substantially circular. Accordingly, the width DL1 of the diaphragm aperture 60 in the parallax direction is substantially equal to the width DL2 of the diaphragm aperture 60 in the direction orthogonal to the parallax direction. On the other hand, as shown in FIG. 17, when the upper diaphragm panel 52 and lower diaphragm panel 54 move in a manner to become closer to each other, the diaphragm aperture 60 becomes smaller and the diaphragm 50 contracts. In this state, the diaphragm aperture 60 is substantially elliptical, with the longer axis being the horizontal axis. Accordingly, concerning the widths of the diaphragm aperture 60, the width in the parallax direction, i.e. the width DL1 of the diaphragm aperture 60 along the arrangement direction of the different partial regions, is longer than the width DL2 of the diaphragm aperture 60 along the direction orthogonal to the parallax direction. In this state, the shape of the diaphragm 50 changes to change the amount of incident light. If there are two parallax directions, such as shown in the embodiments of FIGS. 7 and 8, the width of the diaphragm aperture 60 should be set as described above, with the parallax direction that is focused on being the arrangement direction of the different partial regions as the parallax direction. For example, in a case where the parallax direction includes the horizontal direction and the vertical direction, if the horizontal direction parallax is being focused on, the shape of the diaphragm 50 may be changed such that the width of the diaphragm aperture 60 in the horizontal direction is longer than the width the of the diaphragm aperture 60 in the vertical direction.

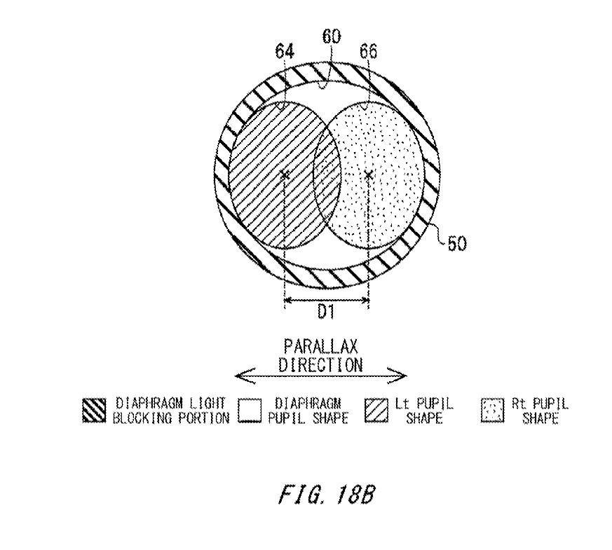

FIG. 18A is a planar view for describing the parallax amount for the diaphragm 50 in the fully open state. FIG. 18B is a front view for describing the parallax amount for the diaphragm 50 in the fully open state. As shown in FIGS. 18A and 18B, the Lt pupil shape 64 of the parallax Lt pixel and the Rt pupil shape 66 of the parallax Rt pixel are formed in corresponding regions within the diaphragm aperture 60 of the diaphragm 50.

The Lt pupil shape 64 is formed with an elliptical shape on the left side of the corresponding region within the diaphragm aperture 60. The Rt pupil shape 66 is formed with an elliptical shape on the right side of the corresponding region within the diaphragm aperture 60. When the diaphragm 50 is in the fully open state, the center of the Lt pupil shape 64 and the center of the Rt pupil shape 66 are separated by a distance D1. The distance between the center of the Lt pupil shape 64 and the center of the Rt pupil shape 66 is correlated with the parallax amount. Accordingly, the change of the parallax, amount is described with relation to the distance between the center of the Lt pupil shape 64 and the center of the Rt pupil shape 66.

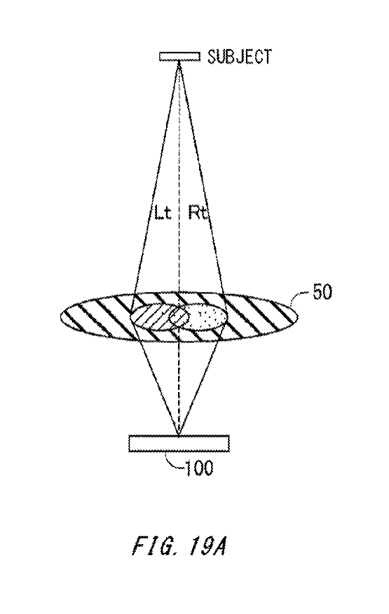

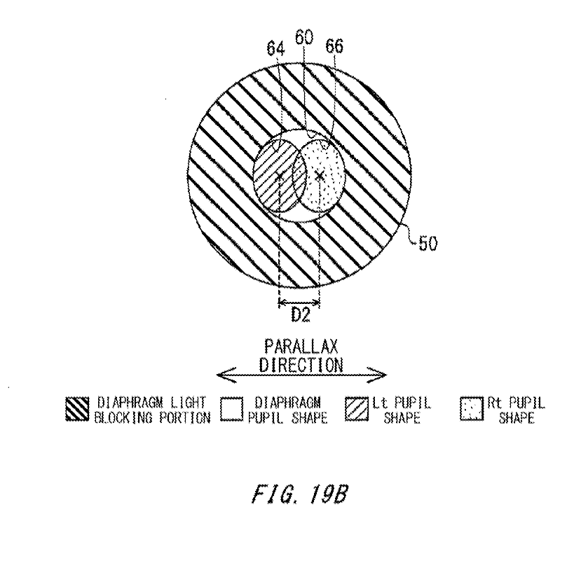

FIG. 19A is a planar view for describing the parallax amount in a state where the diaphragm 50 having an opening that is kept circular is in a contracted state to limit the amount of light. FIG. 19B is a front view for describing the parallax amount in a state where the diaphragm 50 having an opening that is kept circular is in a contracted state to limit the amount of light. As shown in FIGS. 19A and 19B, the Lt pupil shape 64 and the Rt pupil shape 66 have less area than in FIGS. 18A and 18B. Furthermore, as the widths of the Lt pupil shape 64 and the Rt pupil shape 66 in the parallax direction decrease, the positions of the Lt pupil shape 64 and the Rt pupil shape 66 become closer to the center of the diaphragm 50. As a result, the center of the Lt pupil shape 64 and the center of the Rt pupil shape 66 become closer to each other, and therefore the distance D2 between these centers becomes smaller than D1. Accordingly, the parallax amount in the example shown in FIGS. 19A and 19B is less than the parallax amount shown in FIGS. 18A and 18B.

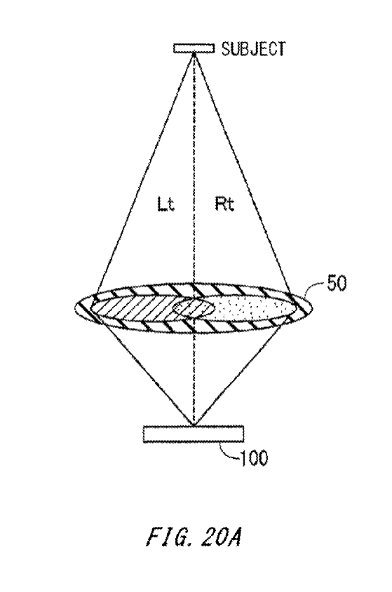

FIG. 20A is a planar view for describing the parallax amount in a state where the diaphragm 50 is in a contracted state. FIG. 208 is a front view for describing the parallax amount in a state where the diaphragm 50 is in a contracted state. The Lt pupil shape 64 and the Rt pupil shape 66 are shorter in the direction orthogonal to the parallax direction, when compared to the example of FIGS. 18A and 188. Furthermore, the area of the Lt pupil shape 64 and the Rt pupil shape 66 is smaller. However, the lengths of the Lt pupil shape 64 and the Rt pupil shape 66 in the parallax direction are almost the same as in the example of FIGS. 18A and 18B. As a result, the distance D3 between the center of the Lt pupil shape 64 and the center of the Rt pupil shape 66 barely changes from the example of FIGS. 18A and 18B, and is substantially equal to D1. Accordingly, the parallax amount in the example of FIGS. 20A and 20B is substantially equal to the parallax amount seen in FIGS. 18A and 18B. In other words, even when the diaphragm 50 is contracted to limit the amount of light, the parallax amount seen in FIGS. 20A and 20B barely changes. Furthermore, the parallax amount of the example shown in FIGS. 20A and 20B is greater than the parallax amount seen in FIGS. 19A and 19B. Accordingly, the change between the parallax amount seen in FIGS. 18A and 18B and the parallax amount seen in FIGS. 20A and 208 is less than the change between the parallax amount seen in FIGS. 18A and 18B and the parallax amount seen in FIGS. 19A and 19B,

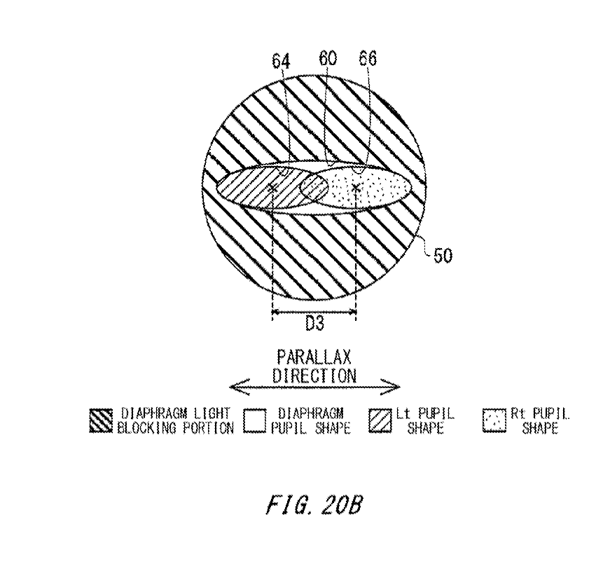

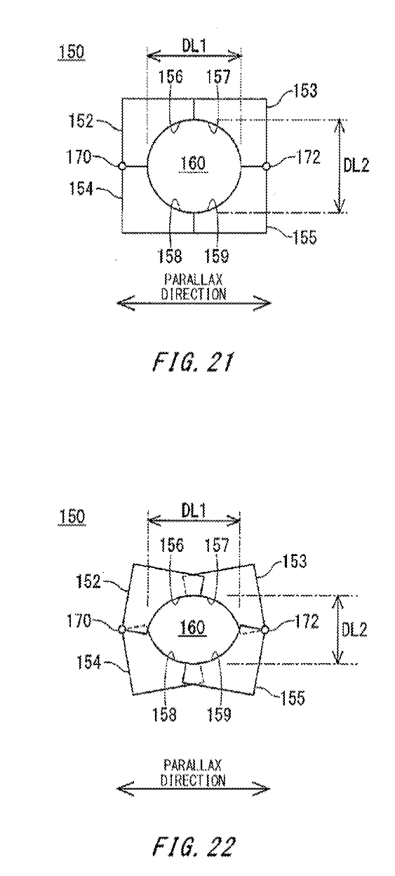

FIG. 21 is a front view for describing another diaphragm 150 in the fully open state. FIG. 22 is a front view for describing the diaphragm 150 of FIG. 21 in the fully open state. As shown in FIG. 21, the diaphragm 150 includes an upper left diaphragm panel 152, a lower left diaphragm panel 154, an upper right diaphragm panel 153, to lower right diaphragm panel 155, a clockwise rotational axis 170, and a counter-clockwise rotational axis 172.

An upper left recess 156 with a quarter-circle shape opening, to the bottom right is formed in the bottom right portion of the upper left diaphragm panel 152. A lower left recess 158 with a quarter-circle shape opening to the top right is formed in the top right portion of the lower left diaphragm panel 154. An upper right recess 157 with a quarter-circle shape opening to the bottom left is formed in the bottom left portion of the upper right diaphragm panel 153. A lower right recess 159 with a quarter-circle shape opening to the top left is formed in the top left portion of the lower right diaphragm panel 155. In an open state, the bottom edge of the upper left diaphragm panel 152 and the top edge of the lower left diaphragm panel 154 are arranged at the same position, and the bottom edge of the upper right diaphragm panel 153 and the top edge of the lower right diaphragm panel 155 are arranged at the same position. Furthermore, in the open state, the right edge of the upper left diaphragm panel 152 and the left edge of the upper right diaphragm panel 153 are arranged at the same position, and the right edge of the lower left diaphragm panel 154 and the left edge of the lower right diaphragm panel 155 are arranged at the same. position. As a result, the upper left recess 156, lower left recess 158, upper right recess 157, and lower right recess 159 form a diaphragm aperture 160 with a substantially circular shape.

The clockwise rotational axis 170 rotatably supports the bottom left edge of the upper left diaphragm panel 152 and the top left edge of the lower left diaphragm panel 154. The counter-clockwise rotational axis 172 rotatably supports the bottom right edge of the upper right diaphragm panel 153 and the top right edge of the lower right diaphragm panel 155.

In the state where the diaphragm 150 is fully open shown in FIG. 21, the diaphragm aperture 160 is substantially circular. On the other hand, as shown in FIG. 22, the upper left diaphragm panel 152 and the lower 101 diaphragm panel 154 respectively rotate clockwise and counter-clockwise on a clockwise rotational axis 170, and the upper right diaphragm panel 153 and the lower right diaphragm panel 155 respectively rotate counter-clockwise and clockwise on a counter-clockwise rotational axis 172. As a result, the diaphragm aperture 160 becomes smaller and the diaphragm 150 contracts. In this state, the diaphragm aperture 160 is substantially an ellipse that is that is long in the horizontal direction, and the width DL1 of the diaphragm aperture 160 in the parallax direction is greater than the width DL2 of the diaphragm aperture 160 in the direction orthogonal to the parallax direction. As a result, the change in the parallax amount when transitioning from the fully open state to the contracted state can be decreased.

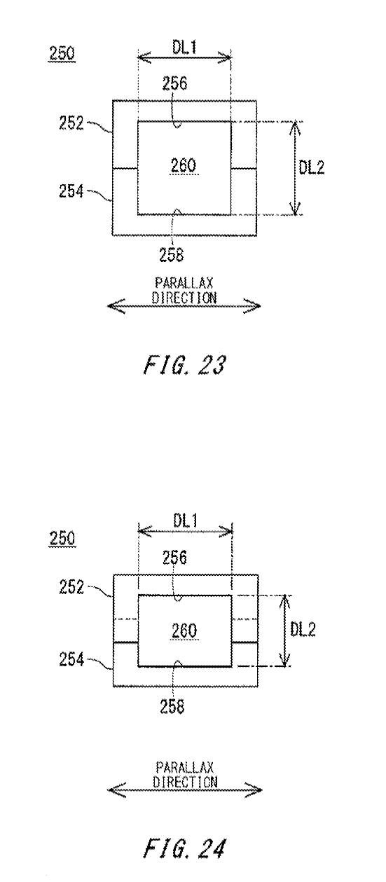

FIG. 23 is a front view for describing another diaphragm 250 in the fully open state. FIG. 24 is a front view for describing the diaphragm 250 of FIG. 23 in the fully open state. As shown in FIG. 23, the diaphragm 250 includes an upper diaphragm panel 252 and a lower diaphragm panel 254. An upper recess 256 with a half-square shape opening downward is formed in the upper diaphragm panel 252. The “half-square” shape is an example of a “rectangular” shape. The upper diaphragm panel 252 is capable of moving downward in the plane of the drawing. A lower recess 258 with a half-square shape opening upward is formed in the lower diaphragm panel 254. The lower diaphragm panel 254 is capable of moving upward in the plane of the drawing. In other words, the upper diaphragm panel 252 and the lower diaphragm panel 254 move relative to each other. In the fully open state, by arranging the bottom edge of the upper diaphragm panel 252 and the top edge of the lower diaphragm panel 254 at substantially the same position, a substantially square diaphragm aperture 260 is formed by the upper recess 256 and the lower recess 258.

On the other hand, as shown in FIG. 24, when the upper diaphragm panel 252 and the lower diaphragm panel 254 move closer to each other, the diaphragm aperture 260 becomes smaller and the diaphragm 250 contracts. In this state, the diaphragm aperture 260 has a rectangular shape that is longer in the horizontal direction. Even in the contracted state, the width DL1 of the diaphragm aperture 260 in the parallax direction is substantially kept the same, and is greater than the width DL2 of the diaphragm aperture 260 in the direction orthogonal to the parallax direction.

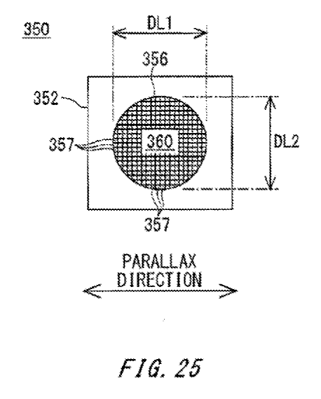

FIG. 25 is a front view for describing another diaphragm 350 in the fully open state. As shown in FIG. 25, the diaphragm 350 includes a base member 352 having a circular diaphragm aperture 360 formed in the center thereof and a substantially circular liquid crystal material 356 forming the diaphragm aperture 360. The liquid crystal material 356 includes a plurality of small liquid crystal sections 357 arranged in a matrix. Each small liquid crystal section 357 switches between a transparent state capable of passing light and a light blocking state capable of blocking light, according to a drive signal input to the diaphragm drive section 206 from the control section 201 provided in the body portion of the digital camera 10. As a result, the diaphragm aperture 360 partially passes the light. The control section 201 controls the liquid crystal material 356 to change the shape of the transparent portion and the light blocking portion of the diaphragm aperture 360. For example, the diaphragm 350 is set to the frilly open state by the control section 201 setting all of the small liquid crystal sections 357 to the transparent state. Furthermore, when contracting the diaphragm 350 for the parallax image capturing, the control section 201 sets the small liquid crystal sections 357 at the top and bottom edges in the plane of the drawing to the light blocking state, and sets the small liquid crystal sections 357 at the right and 101 edges to the transparent state. In this way, the diaphragm 350 maintains a constant width for the diaphragm aperture 360 in the parallax direction, i.e. in the arrangement direction of the different partial regions, and changes the shape of the diaphragm aperture 360 to constrict the light.

The configurations described above may be changed as suitable, e.g. with regard to the shape or number of components. For example, the diaphragm panels of the diaphragm 50 and the like may have different shapes, and the number of diaphragm panels may be changed according to the change in the shape of the diaphragm panels.

When the image capturing lens 20 is exchanged along with the diaphragm, a matching operation may be performed for the characteristics of the new image capturing lens 20 and the information of the image capturing element 100, to determine a shape control parameter for the diaphragm aperture 60 or the like. Examples of the information of the image capturing element 100 include image size, pixel size, parallax characteristics, pixel layout, and the like. Examples of the characteristics of the image capturing lens 20 include focal distance, projected pupil distance, projected pupil shape, image circle, aberration characteristics, diaphragm value, and the like. This is because the subject light illuminating the image capturing element 100 depends on both the lens design information and the lens state. Furthermore, each image capturing element 100 may have a different correlation between parallax pixel angle characteristics and the shape control of the diaphragm aperture. In addition, the electrical signal from the image capturing element 100 due to the photoelectric conversion may be obtained with consideration to the correlation between the parallax pixel angle characteristics and the shape control of the diaphragm aperture. The above characteristics may be taken into consideration to perform an operation to improve the surface uniformity or to perform an operation to maintain linearity between the light intensity and the electrical signal level.

Specifically, control may be performed according to a variety of parameters, such as the shape of the diaphragm aperture accompanying the movement and rotation of the diaphragm panels. For example, when the parameters for controlling the shape of the diaphragm aperture include an additional parameter for changing the diaphragm aperture to an elliptical shape as a parameter for correcting the control of a circular diaphragm, if the diaphragm value is being changed from F4 to F8, the ratio of the width of the diaphragm aperture in the horizontal direction and the width of the diaphragm aperture in the vertical direction may be changed. For example, in a case where the image capturing element 100 is configured to provide a parallax in the horizontal direction, the diaphragm value may be changed from F4 to F8 while changing the ratio of the width of the diaphragm aperture in the horizontal direction and the width of the diaphragm aperture in the vertical direction from (1.0:1.0) to (1.0:0.6), In a case where the image capturing element 100 is configured to provide no parallax, the diaphragm value may be changed from F4 to F8 while maintaining the ratio of the width of the diaphragm aperture in the horizontal direction and the width of the diaphragm aperture in the vertical direction at (1.0:1.0). In a case where the image capturing element 100 is configured to provide a parallax in the vertical direction, the diaphragm value may be changed from F4 to F8 while changing the ratio of the width of the diaphragm aperture in the horizontal direction and the width of the diaphragm aperture in the vertical direction from (1.0:1.0) to (0.6:1.0).

When the focal distance of the image capturing lens 20 is changed, the shape control parameter for the diaphragm aperture 60 or the like may be calculated again based on the new focal distance.

When the digital camera 10 is capable of capturing, moving, images, the diaphragm aperture 60 or the like may be fixed dining the moving image capturing. In this way, it is possible to restrict the decrease in image quality caused by the change in parallax amount and light amount that accompanies the change of the diaphragm aperture 60 or the like.

The above embodiments describe examples of an image capturing apparatus that obtains a parallax image from a single instance of image capturing. However, the present invention is not limited to this, and the diaphragms described above can be adopted in other image capturing apparatuses that include an image capturing element with apertures positioned to respectively pass the light from different partial regions. For example, the diaphragms described above may be adopted in an image capturing apparatus including an image capturing element with an AF function using, the apertures described above.

In the digital camera 10 described above, one or more aperture masks may be provided for the entire image capturing element 100, at or near a position conjugate to the position of the pupil of the image capturing lens 20, which is a single image capturing optical system, Such a digital camera 10 may be provided with the diaphragm 50 described in FIGS. 16 to 25, in addition to this aperture mask. In this case, the aperture mask includes a plurality of apertures that divide the light defined by the image capturing optical system among the different partial regions. For example, the aperture mask includes a pair of circular apertures lined up in the X direction. In this case, the arrangement direction of the partial regions is the X direction. The plurality of apertures open and close in an alternating manner. By capturing images at the timings when the apertures alternately open and close, the image capturing element 100 can acquire a plurality of parallax images corresponding to the partial regions. In this case, the aperture of each pixel of the image capturing element 100 may be the same as the aperture for the non-parallax pixel in FIG. 11 and the like.

Each of the apertures of the aperture mask described above may have a changing shape such as the diaphragms 50 described in FIGS. 16 to 25. In this case, the aperture mask and the diaphragm can be said to have the same function. Also in this case, the apertures open and close in an alternating manner. By capturing images at the timings when the apertures alternately open and close, the image capturing element 100 can acquire a plurality of parallax images corresponding to the partial regions. In this case, the aperture of each pixel of the image capturing element 100 may be the same as the aperture for the non-parallax pixel in FIG. 11 and the like.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed b an apparatus, system, program, and method shown in the claims, embodiments, or diagrams can be performed in any order as long as the order is not indicated by “prior to” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. An image capturing apparatus comprising:
an image capturing element including photoelectric converting elements that are arranged two-dimensionally and photoelectrically convert incident light into an electrical signal, and an aperture mask including apertures provided to correspond one-to-one with the photoelectric converting elements and positioned in a manner to pass light from different partial regions in a cross-sectional region of the incident light; and
a diaphragm that changes shape while maintaining a state in which width of a diaphragm aperture in an arrangement direction of the different partial regions is greater than width of the diaphragm aperture in a direction orthogonal to the arrangement direction.

2. The image capturing apparatus according to claim 1, wherein
the diaphragm includes one diaphragm panel in which one partial-circle recess is formed and another diaphragm panel in which another partial-circle recess is formed opposite the one partial-circle recess, and the other diaphragm panel moves relative to the one diaphragm panel.

3. The image capturing apparatus according to claim 1, wherein
the diaphragm includes one diaphragm panel in which one rectangular recess is formed and another diaphragm panel in which another rectangular recess is formed opposite the one rectangular recess, and the other diaphragm panel moves relative to the one diaphragm panel.

4. The image capturing apparatus according to claim 1, wherein
the diaphragm aperture is formed by a liquid crystal material that is capable of partially passing light.

5. The image capturing apparatus according to claim 4, wherein
when the shape of the diaphragm aperture is changed, the width of the diaphragm aperture in the arrangement direction of the different partial regions is constant.

6. The image capturing apparatus according to claim 4, further comprising:
a body portion to/from which the diaphragm can be attached/detached; and
a control section that is provided in the body portion and controls the liquid crystal material to change the shape of the diaphragm aperture.

7. The image capturing apparatus according to claim 1, wherein
the image capturing apparatus is capable of capturing moving images, and
when capturing moving images, the diaphragm aperture is fixed.

8. The image capturing apparatus according, to claim 1, wherein
the diaphragm is arranged at or near a position conjugate to a position of a pupil of an image capturing lens.

9. The image capturing apparatus according to claim 1, wherein
the image capturing element captures a parallax image with the arrangement direction of the different partial regions being a parallax direction.

10. The image capturing apparatus according to claim 9, wherein
when the shape of the diaphragm aperture is changed, the width of the diaphragm aperture in the parallax direction is constant.

11. The image capturing apparatus according to claim 1, wherein
in the aperture mask, the apertures are arranged two-dimensionally in a repeating manner.

12. An image capturing apparatus comprising:
an image capturing element including photoelectric converting elements that are arranged two-dimensionally and photoelectrically convert incident light into an electrical signal,
an aperture mask that passes light from different partial regions in a cross-sectional region of the incident light to guide the light from the different partial regions to the image capturing element, and
a diaphragm that changes shape while maintaining a state in which width of a diaphragm aperture in an arrangement direction of the different partial regions is greater than width of the diaphragm aperture in a direction orthogonal to the arrangement direction.

13. The image capturing apparatus according to claim 12, further comprising:
a single image capturing optical system that guides the incident light to the image capturing element.

14. The image capturing apparatus according to claim 12, wherein
the aperture mask is provided for the entire image capturing element.

15. The image capturing apparatus according to claim 14, wherein
the aperture mask includes a plurality of apertures that alternate between being open and closed and correspond respectively to the partial regions.

16. The image capturing apparatus according to claim 12, wherein
the diaphragm includes one diaphragm panel in which one partial-circle recess is formed and another diaphragm panel in which another partial-circle recess is formed opposite the one partial-circle recess, and the other diaphragm panel moves relative to the one diaphragm panel.

17. The image capturing apparatus according to claim 12 wherein
the diaphragm includes one diaphragm panel in which one rectangular recess is formed and another diaphragm panel in which another rectangular recess is formed opposite the one rectangular recess, and the other diaphragm panel moves relative to the one diaphragm panel.

18. The image capturing apparatus according to claim 12, wherein
the diaphragm aperture is formed by a liquid crystal material that is capable of partially passing light.

19. The image capturing apparatus according to claim 18, wherein
when the shape of the diaphragm aperture is changed, the width of the diaphragm aperture in the arrangement direction of the different partial regions is constant.

20. The image capturing apparatus according, to claim 18, further comprising:
a body portion to/from which the diaphragm can be attached/detached; and
a control section that is provided in the body portion and controls the liquid crystal material to change the shape of the diaphragm aperture.

21. The image capturing apparatus according to claim 12, wherein
the image capturing apparatus is capable of capturing moving images, and
when capturing moving images, the diaphragm aperture is fixed

22. The image capturing apparatus according to claim 12, wherein
the diaphragm is arranged at or near a position conjugate to a position of a pupil of an image capturing lens.

23. The image capturing apparatus according to claim 12, wherein
the image capturing element captures a parallax image with the arrangement direction of the different partial regions being a parallax direction.

24. The image capturing apparatus according, to claim 23, wherein
when the shape of the diaphragm aperture is changed, the width of the diaphragm aperture in the parallax direction is constant.

25. The image capturing apparatus according to claim 12, wherein
the diaphragm also serves as the aperture mask.
